(19) United States
(12) Patent Application Publication
(10) Pub. No.: US 2002/0182834 A1
(43) Pub. Date: Dec. 5, 2002

(54) Method of manufacturing a transistor with a footed offset spacer

(76) Inventors: Cheng-Tung Huang, Kaohsiung City (TW); Chien-Chien Huang, Taipei City (TW); Sheng-Hao Lin, Chu-Pei City (TW); Yi-Chung Sheng, Hsin-Chu City (TW)

Correspondence Address: POWELL, GOLDSTEIN, FRAZER & MURPHY LLP, P.O. Box 97223, Washington, DC, 20090-7223, US

(21) Appl. No.: 09/865,737

(22) Filed: May 29, 2001

(51) Int. Cl. H01L 21/3205

(52) U.S. Cl. 438/595

(57) ABSTRACT

The present invention provides a method of manufacturing a transistor with a footed offset spacer is disclosed. The method comprises providing a substrate. The gate structure is formed on the substrate and an insulating layer is then formed on the substrate and the gate structure. A portion of said insulating layer is removed by a method of anisotropic dry etching to form the footed offset spacer at a side-wall of the gate structure, wherein the footed offset spacer is formed by adjusting a first flow rate of a first gas and a second flow rate of a second flow gas in the anisotropic dry etching. The footed offset spacer can improve time delay of the propagation and power dissipation.

### BACKGROUND OF THE INVENTION

1. Field of the Invention

The invention relates to a method of manufacturing the spacer of a transistor, and more particularly to a method of manufacturing a transistor with a footed offset spacer.

2. Description of the Prior Art

Typically, offset spacer in a transistor manufacture process is used to lower overlap capacitance between a gate electrode and a source/drain region, which in turn increase the operation rate of the transistor. A structure called an overlay capacitor is a capacitor constructed by the overlay between the gate electrode of a transistor and the source/drain region. The source/drain region of the transistor is adjacent to and under the gate electrode.

As depicted in FIG. 1, there is a source/drain region 118 in a substrate 110. The LDD regions 115 are formed at the sides of the source/drain region 118. A gate structure 120 on a gate oxide 122 is formed above a channel between the LDD regions 115 and an offset spacer 124 is at the side-wall of the gate structure 120. Conventionally, the shape of the offset spacer 124 is like a sheet at the side-wall of the gate structure 120 and modified to adjust the length of the channels of the transistor. However, when the size of the transistor is reduced, such an offset spacer is hard to suppress a gate induced drain leakage (GIDL) effect, cut down device off-state leakage current, and further reduce the gate-to-drain overlap.

### SUMMARY OF THE INVENTION

It is an object of the present invention to provide a manufacture method of the spacer of a transistor. A footed offset spacer is formed to suppress the gate induced drain leakage effect and further cut down the device off-state leakage current.

It is another object of the present invention to provide a method for forming a transistor with a footed offset spacer. The footed offset spacer can reduce the gate-to-drain overlap to improve time delay of the propagation.

In the present invention, a method of manufacturing a transistor with a footed offset spacer is disclosed. The method comprises providing a substrate. The gate structure is formed on the substrate and an insulating layer is then formed on the substrate and the gate structure. A portion of said insulating layer is removed by a method of anisotropic dry etching to form the footed offset spacer at a side-wall of the gate structure, wherein the footed offset spacer is formed by adjusting a first flow rate of a first gas and a second flow rate of a second flow gas in the anisotropic dry etching. The footed offset spacer can improve time delay of the propagation and power dissipation.

### BRIEF DESCRIPTION OF THE DRAWINGS

A better understanding of the invention may be derived by reading the following detailed description with reference to the accompanying drawing wherein:

FIG. 1 is a cross-sectional schematic diagram illustrating a conventional transistor in accordance with the prior art; and

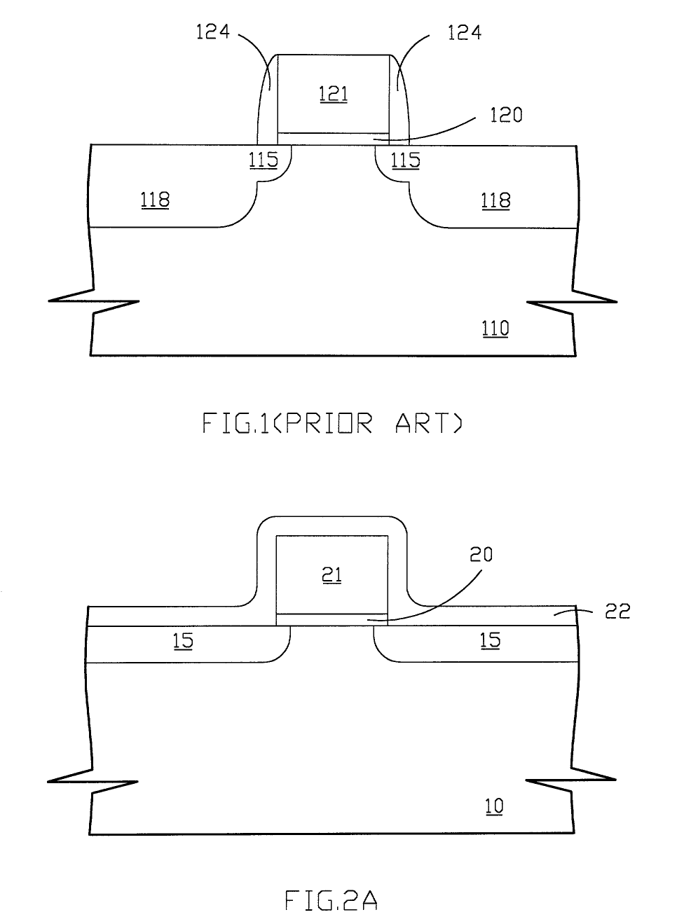

FIGS. 2A-2C are a series of cross-sectional schematic diagrams illustrating a transistor in accordance with the present invention.

### DESCRIPTION OF THE PREFERRED EMBODIMENT

The semiconductor devices of the present invention are applicable to a board range of semiconductor devices and can be fabricated from a variety of semiconductor materials. While the invention is described in terms of a single preferred embodiment, those skilled in the art will recognize that many steps described below can be altered without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, a method of manufacturing a transistor with a footed offset spacer is disclosed. The method comprises providing a substrate. The gate structure is formed on the substrate and an insulating layer is then formed on the substrate and the gate structure. A portion of said insulating layer is removed by a method of anisotropic dry etching to form the footed offset spacer at a side-wall of the gate structure, wherein the footed offset spacer is formed by adjusting a first flow rate of a first gas and a second flow rate of a second flow gas in the anisotropic dry etching. The footed offset spacer can improve time delay of the propagation and power dissipation.

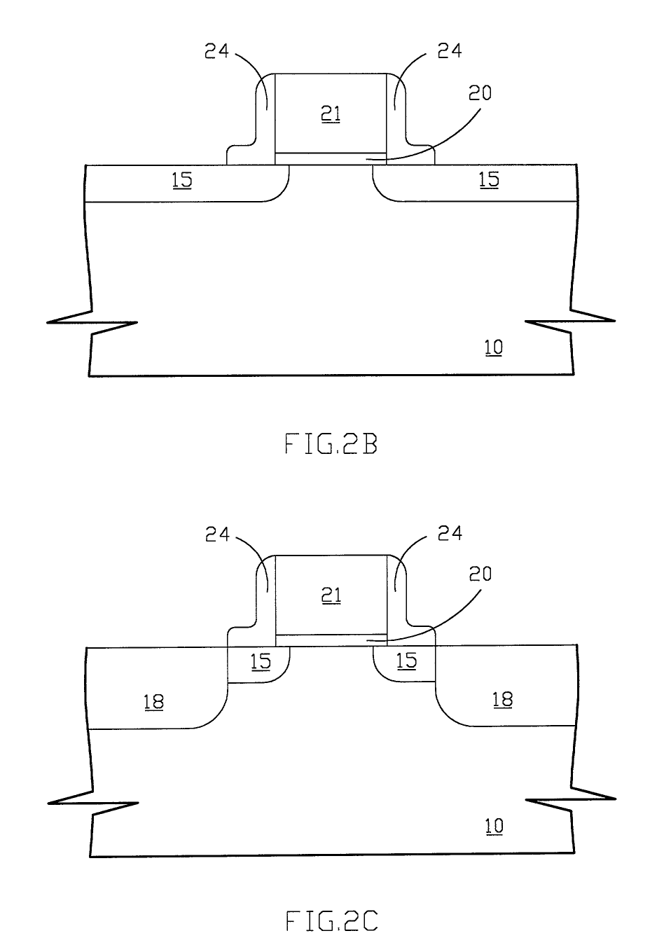

One embodiment of the present invention is depicted in FIGS. 2A-2C. First referring to FIG. 2A, a substrate 10 is provided and thereon a gate oxide layer 20 is formed. Next, a gate electrode 21 is formed on the gate oxide layer 20 by any suitable method. A gate structure consists of the gate oxide layer 20 and the gate electrode 21. Then the lightly doped drain regions 15 are formed by using the gate structure as an implanting mask. In the embodiment, the substrate 10 can be made of silicon doped with p-type ions, such as boron, and the lightly doped drain regions 15 can be made of n-type ions, such as phosphorus. Alternatively, the substrate 10 also can be composed of n-type material and a p-well may be formed in the substrate 10 for an n-type device to be made subsequently. On the other hand, the gate oxide layer 20 may be formed by passing an oxygen rich gas over the surface of the substrate 10. The gate electrode 21 comprises a heavily doped layer of polysilicon by the suitable methods, such as deposition. Next, an insulating layer 22, such as a silicon oxide layer, is conformal deposited on the substrate 10 and the gate electrode 21.

Next, a footed offset spacer 24 with a concave surface is formed by anisotropic dry etching the insulating layer 22. The side profile of the offset spacer and the rate of the anisotropic dry etching may be controlled by adjusting the flows of CHF₃ and CH₄. The following etching conditions may be used: pressures on the order of 1300-1800 mTorr; power on the order of 250-500 Watts; CHF₃ flow between 30-70 sccm; CH₄ flow between 30-70 sccm; Ar flow between 600-1100 sccm; temperature of a bottom electrode in the range of 0° C. to 20° C.; and etching time in the range of 15 to 35 seconds. The formation of the footed offset spacer is advantageous for the gate structure. It is generally known that the vertical electric field in the gate structure may induce both leakage current of a drain and off-state leakage current. In the present invention, the footed offset spacer at the side-wall of the gate structure can reduce the vertical electric field of the gate structure. In addition, the gate-to-drain overlap generally occurs near the gate edges, which increases both time delay of the propagation and power dissipation. The footed offset spacer is so thick near the gate edges that can reduce the capacitance of the gate-to-drain overlap. Thereafter, source/drain regions 18 are formed as shown in FIG. 2C.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of manufacturing a transistor with a footed offset spacer, said method comprising:
providing a substrate and a gate structure thereon;
forming an insulating layer on said substrate and said gate structure; and
removing a portion of said insulating layer by a method of anisotropic dry etching to form said footed offset spacer at a side-wall of said gate structure, wherein said footed offset spacer is formed by adjusting a first flow rate of a first gas and a second flow rate of a second flow gas in said anisotropic dry etching.

2. The method according to claim 1, wherein said first gas is chloroform.

3. The method according to claim 2, wherein said first flow rate is about between 30 and 70 sccm.

4. The method according to claim 1, wherein said second gas is carbon tetrafluoride.

5. The method according to claim 4, wherein said second flow rate is about between 30 and 70 sccm.

6. The method according to claim 1, wherein said anisotropic dry etching has duration of about 15 to 35 seconds.

7. The method according to claim 1, wherein said anisotropic dry etching is implemented at a pressure in the range of 1300 to 1800 mTorr.

8. The method according to claim 1, wherein said anisotropic dry etching is implemented at a power in the range of 250 to 500 watts.

9. The method according to claim 1, wherein said insulating layer comprises a silicon oxide layer.

10. A method of manufacturing a transistor with a footed offset spacer, said method comprising:
providing a substrate and a gate structure thereon;
forming an insulating layer on said substrate and said gate structure; and
removing a portion of said insulating layer by a method of anisotropic dry etching to form said footed offset spacer at a side-wall of said gate structure, wherein said footed offset spacer is formed by adjusting a first flow rate of chloroform gas and a second flow rate of carbon tetrafluoride in said anisotropic dry etching.

11. The method according to claim 10, wherein said first flow rate is about between 30 and 70 sccm.

12. The method according to claim 10, wherein said second flow rate is about between 30 and 70 sccm.

13. The method according to claim 10, wherein said anisotropic dry etching has duration of about 15 to 35 seconds.

14. The method according to claim 10, wherein said anisotropic dry etching is implemented at a pressure in the range of 1300 to 1800 mTorr.

15. The method according to claim 10, wherein said anisotropic dry etching is implemented at a power in the range of 250 to 500 watts.

16. The method according to claim 10, wherein said conformal insulating layer comprises a silicon oxide layer.

17. The method according to claim 10, wherein said gate structure comprises a gate oxide layer and a gate electrode.
